(19) United States
(12) Patent Application Publication
(10) Pub. No.: US 2025/0248139 A1
(43) Pub. Date: Jul. 31, 2025

(54) ENHANCED CHANNEL STRUCTURE FOR HETEROJUNCTION SEMICONDUCTOR DEVICES

(71) Applicant: Taiwan Semiconductor Manufacturing Company, Ltd., Hsinchu (TW)

(72) Inventors: Shih-Min Huang, Hsinchu County (TW); Tzu-Jui Wang, Fengshan City (TW); Yi-Shin Chu, Hsinchu City (TW); Hsiang-Lin Chen, Hsinchu County (TW); Chen-Jong Wang, Hsin-Chu (TW)

(21) Appl. No.: 18/423,587

(22) Filed: Jan. 26, 2024

(51) Int. Cl. H01L 31/111; H01L 27/144; H01L 31/0352

(52) U.S. Cl. CPC H10F 30/26; H10F 39/103; H10F 77/14

(57) ABSTRACT

The present disclosure relates to a photodetector device. The photodetector device includes a semiconductor substrate including a semiconductor material. An absorption region is disposed within the semiconductor substrate. The absorption region includes an epitaxial material that is different than the semiconductor material. A multiplication region is disposed within the semiconductor substrate and separated from the absorption region. A channel region is disposed between the multiplication region and the absorption region, where the channel region and the multiplication region meet at a p-n junction.

### BACKGROUND

Image sensors are solid-state devices that are configured to convert incoming light (e.g., photons) into an electrical signal. The electrical signal is then provided to a processor that can convert the electrical signal to data that can be stored and/or viewed by a user. Integrated chips (ICs) with image sensors are used in a wide range of modern day electronic devices, such as cell phones, security cameras, medical devices, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a photodetector with a heterojunction between semiconductor materials.

FIG. 2 illustrates a cross-sectional view of some additional embodiments of a photodetector device.

FIG. 3 illustrates some embodiments of a top view corresponding to the photodetector device of FIG. 2 at a line A-A′.

FIG. 4 illustrates some embodiments of a cross-sectional view of a photodetector device with a base portion of a surface region that is counter doped and adjacent to a channel region.

FIG. 5 illustrates some embodiments of a cross-sectional view of first and second photodetector devices arranged side-by-side and separated by an isolation structure.

FIGS. 6-7 illustrates a cross-sectional view and top view of some alternative embodiments of a photodetector with a channel region at a heterojunction interface.

FIGS. 8-9 illustrates a cross-sectional view and top view of some alternative embodiments of a photodetector with a channel region at a heterojunction interface.

FIG. 10 illustrates a cross-sectional view of some alternative embodiments of a photodetector with a channel region at a heterojunction interface.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Photodetectors are semiconductor devices designed to convert energy from a radiation source (e.g., light, infrared radiation, x-rays, etc.) into electrical current. Photons or energy from the radiation source incident on an absorption region of a photodetector are absorbed by a semiconductor material of the absorption region. The absorption generates electron-hole pairs separated by an electric field of the photodetector to generate a flow of current (e.g., photocurrent) across a p-n junction within the photodetector where the current is proportional to an intensity of the incident radiation source.

Some photodetectors, for example, avalanche, single photon avalanche, PN, PIN photodetectors, or the like, utilize different semiconductor materials within the photodetector structure. For example, germanium (Ge) can be used in the absorption region, while silicon (Si) serves as a bandgap material and base substrate that facilitates electron channeling from the germanium absorption region to other circuit components through doping regions, electrical wires, and contacts. These devices are heterojunction devices as they have an interface between two different semiconductor types or materials with distinct energy band structures (e.g., Ge—Si interface). Additionally, heterojunction devices can include a p-n junction between the doped absorption region and a doped region of the base substrate separated by an intrinsic region. That is, an interface at the heterojunction can be between a doped region of an epitaxial material and an intrinsic region of a semiconductor material. While heterojunction devices offer advantages like enhanced carrier mobility, high speed-performance, and lower power consumption, they can also exhibit adverse characteristics like dark current leakage due to high defect densities at the heterojunction interface. The defect densities at the heterojunction interface (Ge—Si interface), can arise from a lattice mismatch, band offset, and interface states between different crystal structures of the materials with differing bandgaps. As a result, heterojunction devices can suffer from low electron transfer ratios since the defects at the heterojunction can hinder electron transfer.

The present disclosure, in some embodiments, relates to a heterojunction device having a photodetector with an absorption region of an epitaxial material (e.g., a Ge semiconductor material) surrounded by a semiconductor substrate (e.g., a Si semiconductor material) that facilitates electron channeling from the absorption region to other circuit components through doping regions, electrical wires, and contacts. The heterojunction device has an enhanced channel region (hereinafter referred to as “channel region”) at the heterojunction between the epitaxial material and a doped region of the base substrate. The channel region is doped with a first doping type that is opposite a second doping type of the absorption region, thus a p-n junction is formed at the heterojunction which increases the electron transfer rate through the heterojunction by “funneling” electrons through the heterojunction interface. As a result, the heterojunction interface is enhanced thereby increasing the electron transfer rate at the interface.

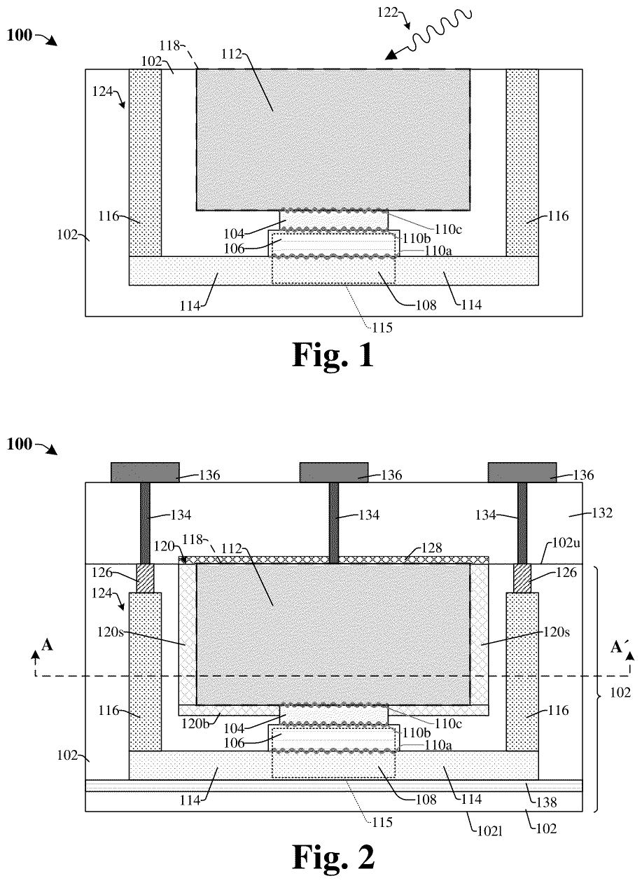

FIG. 1 illustrates a cross-sectional view of some embodiments of a photodetector device 100 with a channel region that is doped and meets an absorption region. In some embodiments, the photodetector device 100 is an avalanche photodetector or a single-photon avalanche diode.

Photodetector device 100 comprises a semiconductor substrate 102 comprising a semiconductor material. An absorption region 112 is disposed within the semiconductor substrate 102. The absorption region 112 comprises an epitaxial material different than the semiconductor material. In some embodiments, the absorption region 112 has a fill factor of 1% to 99% of the area laterally spanned by the photodetector device 100 with a height of 0.1 micrometers to 3 micrometers. In some embodiments, the semiconductor material is silicon (Si) and the epitaxial material is germanium (Ge), but it is understood that the materials can be reversed. In some embodiments, for example, the absorption region 112 can comprise a p-type dopant. In some embodiments the absorption region 112 is Ge p-type doped to a concentration of 1e16 atoms/cm³ to 1e18 atoms/cm³. A heterojunction interface 118 is located at a surface of the absorption region 112 that abuts a surface of the semiconductor substrate 102. In some embodiments, the heterojunction interface 118 is a Ge—Si interface.

The heterojunction interface 118 is present where outer sidewalls and a lower surface of the absorption region 112 meet inner sidewalls and a recessed upper surface, respectively, of the semiconductor substrate 102. In some embodiment (e.g., in FIG. 2), the semiconductor substrate 102 is doped at the heterojunction interface 118. In some embodiments the heterojunction interface 118 is comprised of a Ge—Si alloy having a lattice constant ranging between approximately 56.6 nanometers (nm) and approximately 54.3 nm. In some cases, the heterojunction interface 118 can have a thickness ranging from 1 angstrom to 20 nm, from 10 angstroms to 10 nm, or other similar values. In some embodiments, the heterojunction interface can have a cross-section that is U-shaped.

A multiplication region 115 is disposed within the semiconductor substrate 102 and is separated from the absorption region 112. The multiplication region 115 includes a first doped region 106 arranged below the absorption region 112 (e.g., epitaxial material) and a second doped region 108 arranged below and abutting the first doped region 106 at a first p-n junction 110a. In some embodiments, the first doped region 106 and the second doped region 108 have different doping types. For example, the first doped region 106 can be p-type and the second doped region 108 can be n-type. Thus, in some embodiments, the multiplication region 115 comprises an n-type region with an n-type dopant and a p-type region with a p-type dopant.

A lateral connection region 114 extends laterally from the second doped region 108 past outer sidewalls of the absorption region 112 where the lateral connection region 114 comprises the same doping type as the second doped region 108. A vertical connection region 116 extends from the lateral connection region 114 and vertically past a bottom surface of the absorption region 112. The vertical connection region 116 comprises the same doping type as the lateral connection region 114. Furthermore, the lateral connection region 114 and the vertical connection region 116 form a connection region 124. In some contexts, the connection region 124 is referred to as a “guard ring” as the vertical connection region 116 laterally surrounds the absorption region 112.

A channel region 104 is disposed between the multiplication region 115 and the absorption region 112. The channel region 104 and the multiplication region 115 meet at a second p-n junction 110b. Furthermore, the channel region 104 and the absorption region 112 meet at a third p-n junction 110c. In some embodiments, the channel region 104 is referred to as a third doped region and can comprise the same doping type as the second doped region 108. In some embodiments, the channel region 104 comprises an n-type region with an n-type dopant and the p-type dopant of the multiplication region is disposed between the channel region 104 and the n-type region of the multiplication region. In some embodiments, the channel region 104 has a doping concentration of 1e16 atoms/cm³ to 1e18 atoms/cm³. In some embodiments the channel region 104 and the absorption region 112 have substantially the same doping concentration. The channel region 104 is disposed within the semiconductor substrate 102 and thus the multiplication region 115 and the channel region 104 comprise the semiconductor material. As such, the heterojunction interface 118 extends between the absorption region 112 and the channel region 104. In some embodiments, a lateral width of the channel region 104 is between 0.4 micrometers (μm) to substantially a same lateral width as the absorption region 112, and the channel region 104 can have a height from 0.1 μm to 3 μm.

In some embodiments, during operation of the photodetector device 100, a bias circuit (not shown) biases the first p-n junction 110a above a breakdown voltage. Under this bias condition, when an incident photon 122 (or energy, e.g., from a radiation source) is absorbed in the absorption region 112, an electron-hole pair is created and the electron drifts through the channel region 104 and into a multiplication region 115, which includes the first p-n junction 110a. The electron passes through the second p-n junction 110b between the channel region 104 and the multiplication region 115, and the electron passes through the third p-n junction 110c between the channel region 104 and the absorption region 112. As such, the channel region defines the electron path there by “funneling” or facilitating transfer of the electron through the heterojunction interface 118 at the third p-n junction 110c and into the multiplication region 115. The electron is then accelerated in the multiplication region 115, gaining sufficient kinetic energy to undergo impact ionization, creating a secondary electron-hole pair. The second electron and hole of the second electron-hole pair are in turn accelerated and impact ionized, creating further electron-hole pairs in the multiplication region 115. Further impact ionization of holes and electrons multiply thus rapidly creating a large current (e.g., avalanche current) which can be self-sustaining if the device is biased above a breakdown voltage (e.g., avalanche breakdown). In these conditions, an observable electronic signal is produced, which can be timed in relation to the initial incident photon. After detection, the bias circuit momentarily biases the photodetector device 100 below the breakdown voltage to quench the multiplication, after which the photodetector device 100 can return to its quiescent state ready to detect further incident photons.

In photodetector device 100, forming the channel region 104 from a doped material that is opposite of a doping of the absorption region 112, rather than, for example, forming the channel region from intrinsic material, offers several advantages. For example, the third p-n junction 110c increases the electron transfer rate through the heterojunction by “funneling” electrons through the heterojunction interface 118 and to the multiplication region 115 of the semiconductor substrate 102. As a result, the heterojunction interface is enhanced thereby increasing the electron transfer rate at the interface. Meanwhile, current leakage and dark currents that arise as a result of a crystalline mismatch and defects at the heterojunction interface 118 can still be suppressed by a doped Si region surrounded the absorption region 112, for example, the surface region 120 of FIG. 2.

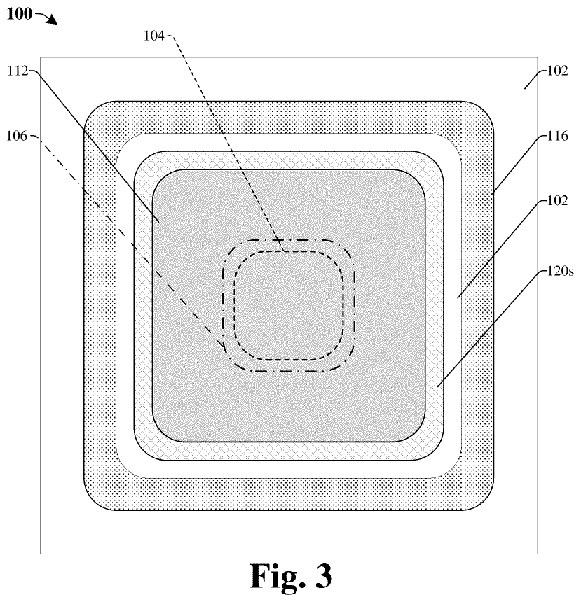

FIG. 2 illustrates a cross-sectional view of some additional embodiments of a photodetector device 100. FIG. 3 illustrates some embodiments corresponding to a top view of the photodetector device 100 of FIG. 2 at the A-A′ line.

Referring now to FIGS. 2 and 3 concurrently, photodetector device 100 of FIGS. 2 and 3 include additional embodiments not shown in FIG. 1. The photodetector device 100 includes an epitaxial material (e.g., within absorption region 112) disposed within the semiconductor substrate 102. A first doped region 106 is arranged in the semiconductor substrate 102 below the epitaxial material. A second doped region 108 is arranged in the semiconductor substrate 102 below the first doped region 106 and abutting the first doped region 106 at a first p-n junction 110a. A third doped region (e.g., the channel region 104) is disposed between the epitaxial material and the first doped region 106. The third doped region abuts the first doped region 106 at a second p-n junction 110b, and the third doped region abuts the epitaxial material at a third p-n junction 110c. As such, the first doped region 106 is disposed on top of the second doped region 108, the third doped region is disposed on top of the first doped region, and the epitaxial material is on top of the third doped region. In some embodiments, the first doped region 106 extends past outer edges of the third doped region.

A surface region 120 extends around a bottom surface and sidewalls of the absorption region 112 to an upper surface 102u of the semiconductor substrate 102. The surface region 120 comprises a doped portion of the semiconductor substrate 102. In some embodiments the surface region 120 comprises the same dopant type as the absorption region and at a similar doping concentration. The surface region 120 comprises a base portion 120b having a central opening corresponding to the channel region 104, and includes a sidewall portion 120s extending upwards along outer sidewalls of the absorption region 112. In some embodiments, the base portion 120b and the sidewall portion 120s have different thicknesses, for example, where the base portion 120b is thinner than the sidewall portion 120s. The multiplication region 115 is disposed within the semiconductor substrate 102 separated from the absorption region 112. The multiplication region 115 includes a first doped region 106 arranged below the absorption region 112, and a second doped region 108 arranged below and abutting the first doped region 106 at the first p-n junction 110a. As such, the channel region 104 extends from the multiplication region 115 and through the surface region 120 to abut the absorption region 112 at the heterojunction interface 118.

In some embodiments, a thickness of the channel region 104 is greater than a thickness of the base portion 120b of the surface region 120. In some embodiments, a width of the channel region 104 is less than a width of the first doped region 106. As such, the base portion 120b of the surface region 120 is separated from the first doped region 106 of the multiplication region 115 by the semiconductor substrate 102. Furthermore, the channel region 104 abuts the multiplication region 115, semiconductor substrate 102, and the surface region 120. The surface region 120 establishes a partial U-shaped cross-sectional (FIG. 2) profile that extends from the channel region 104 and generally encloses the absorption region 112. From a top-view (FIG. 3), the surface region 120 is ring-shaped where the surface region 120 laterally surrounds the absorption region 112. In some embodiments, the surface region 120 extends laterally past the epitaxial material and extends vertically along outer edges of the epitaxial material to an upper surface of the substrate.

The surface region 120 comprises the semiconductor material and is doped with the same doping type as the absorption region 112. In some embodiments, for example, the absorption region 112 is p-type and the surface region 120 is p-type. In other examples, the absorption region 112 is Ge doped p-type and the surface region 120 is Si doped p-type. Because the absorption region 112 and the surface region 120 comprise different bandgap materials, the absorption region 112 and the surface region 120 abut at the heterojunction interface 118. The surface region 120 around the absorption region 112 may reduce current leakage, and thus may mitigate dark current that arises due to stress, dislocations, and the like arising at the Ge—Si interface region.

In some embodiments, a contact structure 126 extends from the vertical connection region 116 to a top surface of the semiconductor substrate 102. The contact structure 126 can, for example, comprise the same semiconductor material and same doping type as the vertical connection region 116. In some embodiments, the contact structure 126 has a higher doping concentration than the vertical connection region 116. Thus, the connection region 124 can include the contact structure 126, the lateral connection region 114 and the vertical connection region 116, which are separated from the absorption region 112 and the surface region 120 by the semiconductor substrate 102.

The lateral connection region 114 extends laterally from the second doped region 108 past outer sidewalls of the first doped region 106 and outer sidewalls of the absorption region 112. The vertical connection region 116 extends vertically from the lateral connection region 114 past the channel region 104 and a bottom surface of the absorption region 112. In some contexts, the connection region 124 may be referred to as a “ring-shaped” because the vertical connection region 116 laterally surrounds the absorption region 112 when viewed from above (FIG. 3). In some embodiments, the second doped region 108, and the connection region 124 collectively establish a U-shaped cross-sectional profile that generally enclose the first doped region 106, the channel region 104, and the absorption region 112 when viewed in a cross-sectional view (FIG. 2). In some embodiments, an isolation layer 138 is disposed within the semiconductor substrate 102 below the connection region 124. The isolation layer 138 can, for example, comprise the semiconductor material of the semiconductor substrate 102 and can be doped (e.g., p-type).

A dielectric structure 132 extends over the upper surface 102u of the semiconductor substrate 102. The dielectric structure 132 can be or comprise a silicon dioxide or a low-k dielectric material. An epitaxial cap 128 is disposed within the dielectric structure 132, where the epitaxial cap 128 extends from an upper surface of the absorption region 112. The epitaxial cap 128 extends past outer sidewalls of the absorption region 112 and over a top surface of the sidewall portion 120s of the surface region 120. Conductive contacts 134, such as metal contacts, extend through the dielectric structure 132. The conductive contacts 134 couple to the contact structure 126 and one of the conductive contacts 134 extend through the epitaxial cap 128 to couple to the absorption region 112. Metal lines 136 are coupled to the conductive contacts and operably coupled to a bias circuit (not shown), which may include semiconductor devices formed on the semiconductor substrate 102 or formed on another semiconductor substrate. For example, if the semiconductor devices are formed on the semiconductor substrate 102, the semiconductor devices may include transistors including fins and/or a gate electrode disposed on the upper surface 102u of the semiconductor substrate 102, or alternatively may include transistors including fins and/or a gate electrode disposed on the lower surface 1021 of the semiconductor substrate 102 in which case a through via may extend through the semiconductor substrate 102 to facilitate the operable coupling.

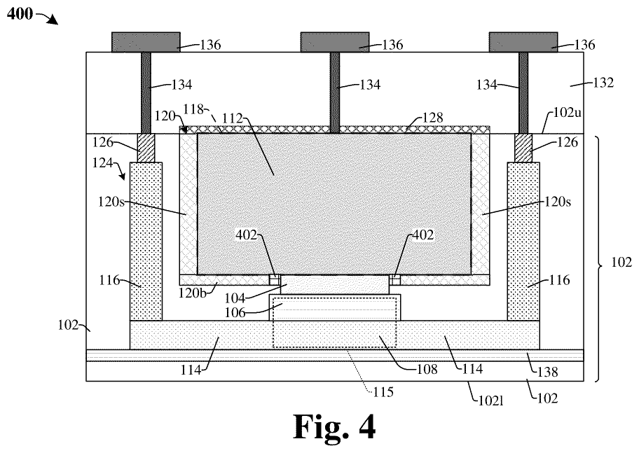

FIG. 4 illustrates some embodiments of a cross-sectional view of some additional embodiments of a photodetector device 400 with a base portion 120b of a surface region 120 that is counter doped. That is, the surface region 120 is doped with a first type of dopant, then subsequently doped with a second type of dopant that is different than the first type.

Photodetector device 100 of FIG. 4 shows similar features as FIG. 2 with an alternative embodiment for the base portion 120b of the surface region 120. The base portion 120b comprises the same doping type as the sidewall portion 120s of the surface region 120. A subset base portion 402 of the base portion 120b has a different doping concentration relative to the sidewall portion 120s. The subset base portion 402 is disposed along outer sidewalls of the channel region 104 and abutting the absorption region 112. The subset base portion 402 is formed according to a counter doping process. The subset base portion 402 is formed with a first doping type according to a first doping process and subsequently a second doping type according to a second doping process where the first and second doping types are different. For example, in some embodiments, the subset base portion 402 is formed with an n-type dopant (e.g., first doping type) during the first doping process, then a mask is placed over the channel region 104 and the subset base portion 402 in conjunction with the base portion 120b is further formed with a p-type dopant (e.g., second doping type) during the second doping process. The second doping process counteracts the effects of the first doping process and forms the subset base portion 402 to be the second doping type according to the counter doping process. This process has the advantage of minimizing the processing steps to form the channel region 104 and the surface region 120.

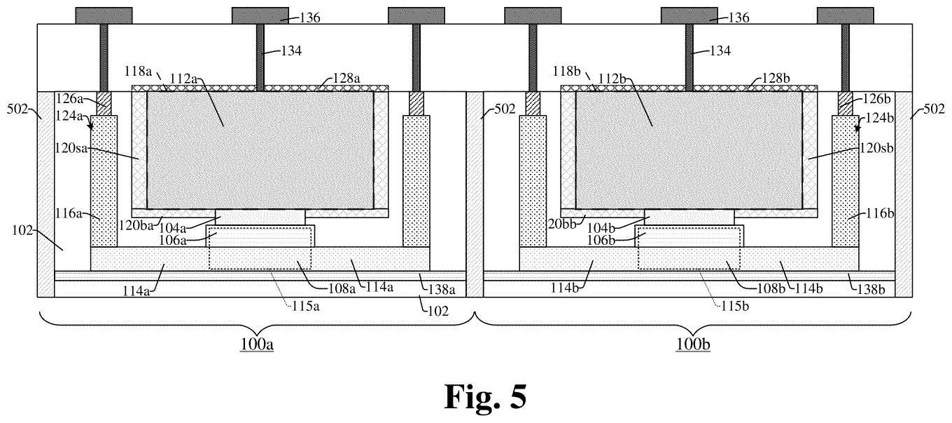

FIG. 5 shows some embodiments of a cross-sectional view of some embodiments where first and second photodetector devices are arranged side-by-side in a semiconductor substrate 102 and separated by an isolation structure 502. In FIG. 5, a first photodetector device 100a and a second photodetector device 100b have features as previously described in FIG. 2, wherein features marked with “a” and “b” have the same or similar structure and function as described with regards to FIG. 2 (e.g., 112a and 112b in FIG. 5 correspond to 112 in FIG. 2). Thus, in FIG. 5, a first vertical connection region 116a laterally surrounds a first absorption region 112a of the first photodetector device 100a, and a second vertical connection region 116b laterally surrounds a second absorption region 112b of the second photodetector device 100b. The isolation structure 502 separates the first vertical connection region 116a from the second vertical connection region 116b and defines an isolation structure 502. In some embodiments, the isolation structure 502 is intrinsic (e.g., monocrystalline silicon). In other embodiments, the isolation structure 502 is a deep trench isolation structure made of a dielectric material and/or including a doped portion of the semiconductor substrate 102 (e.g., doped p-type). It will be appreciated that any number of photodetector devices can be arranged in the semiconductor substrate 102, and they can be arranged in an array, for example, that includes a number of rows and columns. Also, although FIG. 5 is illustrated in an example where the first photodetector device 102a and the second photodetector device 102b correspond to the photodetector device of FIG. 2, in other embodiments the first photodetector device 102a and the second photodetector device 102b could correspond to other illustrated embodiments described herein, or combination thereof.

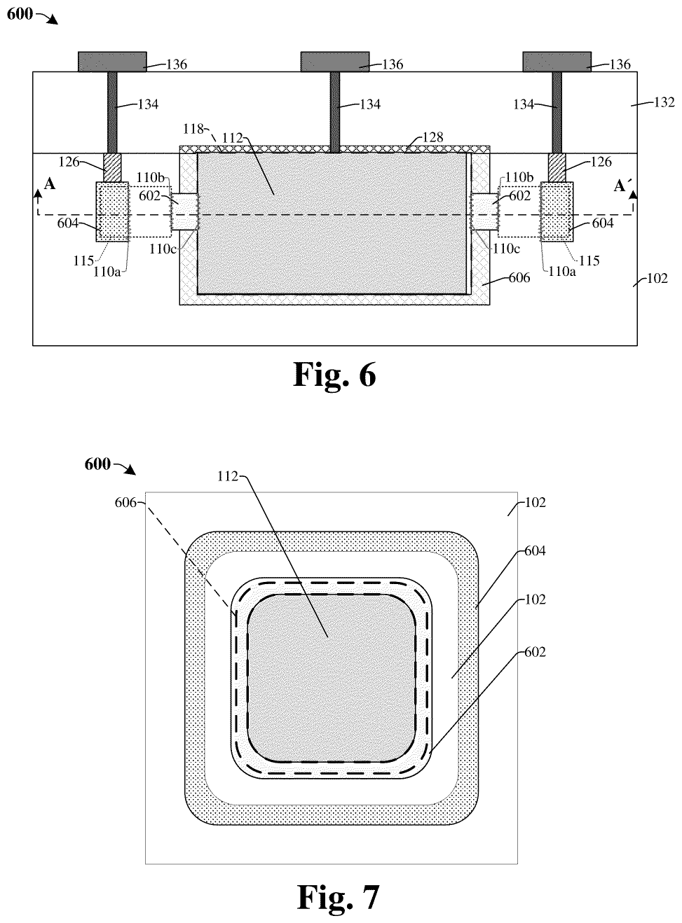

FIG. 6 illustrates a cross-sectional view of some alternative embodiments of a photodetector device 600 with a channel region 602 at a heterojunction interface 118. FIG. 7 illustrates some embodiments corresponding to a top view of the photodetector device 600 at the A-A′ line of FIG. 6. In some embodiments, the photodetector device 600 is a PN or a PIN photodetector.

Referring now to FIGS. 6 and 7 concurrently, photodetector device 600 shows alternative features relative to photodetector device 100 with a channel region 602 that is ring shaped. The absorption region 112 is disposed within the semiconductor substrate 102. A surface region 606 is disposed along an outer perimeter of the absorption region 112 in a cross-sectional view (FIG. 6). In some embodiments, the surface region 606 and the absorption region 112 of FIGS. 6 and 7 are analogous to the surface region 120 and absorption region 112 of FIGS. 2-5. A first doped region 604 is laterally separated from the surface region 606 by the semiconductor substrate 102. The first doped region 604 is coupled to conductive contacts 134 through a contact structure 126.

A channel region 602 meets the absorption region 112 at the heterojunction interface 118 at opposing sidewalls of the absorption region 112. The channel region 602 extends from the semiconductor substrate 102 and through the surface region 606. Thus, the channel region 602 is disposed on outer sidewalls of the absorption region 112. Furthermore, the channel region 602 is separated from the first doped region 604 by the semiconductor substrate 102. That is, intrinsic substrate of the semiconductor substrate 102 is disposed between the channel region 602 and the first doped region 604. The channel region 602 defines a ring shape from a top view (FIG. 7) that laterally surrounds the absorption region 112. Furthermore, the surface region 606 extends from the channel region 602 where the surface region 606 is disposed along sidewalls of the absorption region 112 and a bottom surface of the absorption region 112.

In some embodiments, the first doped region 604 and the channel region 602 comprise the same doping type, for example, the first doping type. The absorption region 112 comprises a second doping type that is different than the first doping type. For example, the first doping type can be n-type and the second doping type can be p-type. Thus, the channel region 602 meets the absorption region 112 at a p-n junction which is co-located with the heterojunction interface 118 at a sidewall of the channel region 602. As such, when photodetector device 600 is biased and excited by a radiation source, a current is generated from the absorption region 112, through the channel region 602, through the semiconductor substrate 102 and to the first doped region 604. The channel region 602 facilitates electron transfer through the heterojunction interface 118.

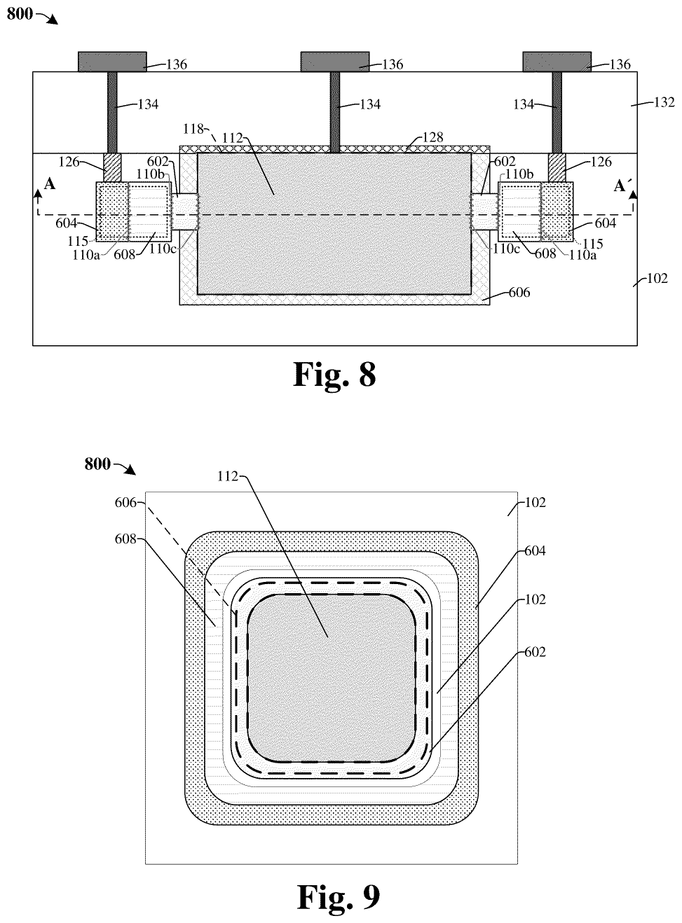

FIG. 8 illustrates a cross-sectional view of some alternative embodiments of a photodetector device 800 with a channel region at a heterojunction interface. FIG. 9 illustrates some embodiments corresponding to a top view of the photodetector device 800 at an A-A′ line of FIG. 8. In some embodiments, the photodetector device 800 is an avalanche photodetector or a single-photon avalanche diode.

Referring now to FIGS. 8 and 9 concurrently, photodetector device 800 shows alternative features relative to photodetector device 600 where a second doped region 608 is disposed between the channel region 602 and the first doped region 604. In some embodiments the channel region 602 is referred to as a third doped region. The first doped region 604 and the channel region 602 comprise the same doping type as discussed in accordance with FIGS. 6-7. The second doped region 608 comprises a second doping type that is different than the first doping type of the channel region 602 and the first doped region 604. For example, in some embodiments the first doping type is n-type and the second doping type is p-type. As such, a first p-n junction is formed between the first doped region 604 and the second doped region 608, a second p-n junction is formed between the second doped region 608 and the channel region 602, and a third p-n junction is formed between the channel region 602 and the absorption region 112 at the heterojunction interface 118. The first doped region 604 and the second doped region 608 form a multiplication region 115 of the photodetector device 600. The multiplication region 115 laterally surrounds the channel region 602 and the absorption region 112 thus forming a ring shaped multiplication region from a top view (FIG. 9). The channel region 602 facilitates electron transfer through the heterojunction interface 118 and into the multiplication region 115 as described in accordance with FIGS. 1 and 2.

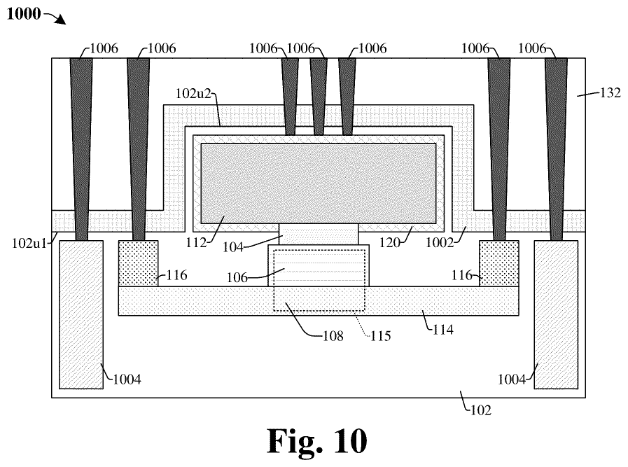

FIG. 10 illustrates some embodiments corresponding to a cross-sectional view of a mesa type photodetector device 1000 with a channel region at a heterojunction interface.

Mesa type photodetector device 1000 shows an alternative embodiment where some aspects of the photodetector device are disposed between two upper surfaces of the semiconductor substrate 102. For example, one or more of the absorption region 112, the surface region 120, or the channel region 104 can extend above a first upper surface 102u1 of the semiconductor substrate 102. In some embodiments, a second upper surface 102u2 of the semiconductor substrate 102 extends over the absorption region 112 and the surface region 120. In some embodiments, the multiplication region 115 is disposed below the first upper surface 102u1. An isolation structure 1004 is disposed within the semiconductor substrate 102 connected to metal contacts 1006 and laterally offset from the vertical connection region 116. The isolation structure 1004 isolates the photodetector from surrounding devices within the semiconductor substrate 102. A liner 1002 is disposed over the semiconductor substrate 102 extending along the first upper surface 102u1 and the second upper surface 102u2 of the semiconductor substrate 102. In some embodiments, the liner 1002 can be, for example, a dielectric liner. Metal contacts 1006 contact the surface region and the vertical connection region 116 to bias the mesa type photodetector device 1000.

In some embodiments, the present disclosure relates to a photodetector device. The photodetector device includes a semiconductor substrate with a semiconductor material. An absorption region is disposed within the semiconductor substrate. The absorption region includes an epitaxial material that is different than the semiconductor material. A multiplication region is disposed within the semiconductor substrate and is separated from the absorption region.

In other embodiments, the present disclosure relates to a heterojunction device. The heterojunction device includes an epitaxial material disposed between sidewalls of the substrate. A first doped region is arranged in the substrate adjacent to the epitaxial material. A second doped region is arranged in the substrate adjacent to the first doped region and abuts the first doped region at a first p-n junction. A third doped region is disposed between the epitaxial material and the first doped region, where the third doped region abuts the first doped region at a second p-n junction. A surface region extends from the third doped region and along a perimeter of the epitaxial material where the surface region includes a same dopant type as the first doped region.

In yet other embodiments, the present disclosure relates a semiconductor device. The semiconductor device includes a substrate and an absorption region disposed within the substrate. A first doped region is disposed within the substrate and laterally separated from the absorption region. The first doped region laterally surrounds the absorption region. A channel region is disposed within the substrate. The channel region is disposed on outer sidewalls of the absorption region and laterally surrounds the absorption region. A multiplication region, that includes the first doped region, extends between the first doped region and the channel region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photodetector device comprising:
a semiconductor substrate comprising a semiconductor material;
an absorption region disposed within the semiconductor substrate, the absorption region comprising an epitaxial material different than the semiconductor material;
a multiplication region disposed within the semiconductor substrate and separated from the absorption region; and
a channel region disposed between the multiplication region and the absorption region, wherein the channel region and the multiplication region meet at a p-n junction.

2. The photodetector device of claim 1, wherein the multiplication region and the channel region comprise the semiconductor material.

3. The photodetector device of claim 1, wherein the channel region comprises an n-type region, and the multiplication region comprises a n-type region and a p-type region, wherein the p-type region of the multiplication region is disposed between the channel region and the n-type region of the multiplication region.

4. The photodetector device of claim 1, further comprising:
a surface region that extends around a bottom surface and sidewalls of the absorption region, and wherein the surface region comprises the semiconductor material doped with a same doping type as the absorption region.

5. The photodetector device of claim 4, wherein the channel region extends from the multiplication region and through the surface region.

6. The photodetector device of claim 4, wherein the channel region abuts the multiplication region, the semiconductor substrate, and the surface region.

7. The photodetector device of claim 1, further comprising:
a connection region comprising a lateral connection region and a vertical connection region that are doped, wherein the connection region is separated from the absorption region by the semiconductor substrate, and the connection region extends from the multiplication region, and substantially encloses the absorption region.

8. A heterojunction device comprising:
a substrate;
an epitaxial material disposed between sidewalls of the substrate;
a first doped region arranged in the substrate adjacent to the epitaxial material;
a second doped region arranged in the substrate adjacent to the first doped region abutting the first doped region at a first p-n junction;
a third doped region disposed between the epitaxial material and the first doped region, wherein the third doped region abuts the first doped region at a second p-n junction; and
a surface region extending from the third doped region and along a perimeter of the epitaxial material wherein the surface region comprises a same dopant type as the first doped region.

9. The heterojunction device of claim 8, wherein the third doped region extends through the surface region to abut the epitaxial material.

10. The heterojunction device of claim 8, wherein the surface region extends laterally past the epitaxial material, and extends vertically along outer edges of the epitaxial material to an upper surface of the substrate.

11. The heterojunction device of claim 8, wherein the surface region extends from opposing sidewalls of the third doped region.

12. The heterojunction device of claim 8, wherein the first doped region is separated from the surface region by the third doped region.

13. The heterojunction device of claim 8, further comprising:
an lateral connection region that extends laterally from the second doped region past outer sidewalls of the first doped region and the epitaxial material; and
a vertical connection region that extends from the lateral connection region vertically past the third doped region and a bottom surface of the epitaxial material.

14. The heterojunction device of claim 13, further comprising:
a contact structure that extends from the vertical connection region to an upper surface of the substrate.

15. The heterojunction device of claim 8, wherein the first doped region is disposed on top of the second doped region, the third doped region is disposed on a top surface of the first doped region, and the first doped region extends past outer edges of the third doped region.

16. The heterojunction device of claim 8, further comprising:
an epitaxial cap extending from an upper surface of the epitaxial material.

17. A semiconductor device comprising:
a substrate;
an absorption region disposed within the substrate;
a first doped region disposed within the substrate and laterally separated from the absorption region, wherein the first doped region laterally surrounds the absorption region;
a channel region disposed within the substrate, wherein the channel region is disposed on outer sidewalls of the absorption region and laterally surrounds the absorption region; and
a multiplication region that comprises the first doped region and extends between the first doped region and the channel region.

18. The semiconductor device of claim 17, further comprising:
a surface region extending from the channel region wherein the surface region is disposed along sidewalls of the absorption region and a bottom surface of the absorption region, wherein the surface region and the absorption region comprise a first doping type.

19. The semiconductor device of claim 17, further comprising:
a second doped region disposed within the multiplication region, wherein the second doped region extends between the channel region and the first doped region, and wherein the absorption region and the second doped region comprise a first doping type and the first doped region and the channel region comprise a second doping type that is different from the first doping type.

20. The semiconductor device of claim 17, wherein the first doped region abuts the substrate at a first p-n junction, the channel region abuts the substrate at a second p-n junction, and the channel region abuts the absorption region at a third p-n junction.
